(19) United States
(12) Patent Application Publication
(10) Pub. No.: US 2025/0234740 A1
(43) Pub. Date: Jul. 17, 2025

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Xiaoxue WEN, Beijing (CN); Ming HU, Beijing (CN); Taofeng XIE, Beijing (CN); Bo SHI, Beijing (CN); Chi YU, Beijing (CN); Cuicui TAN, Beijing (CN); Zhuangqi ZHOU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/704,500

(22) PCT Filed: Mar. 28, 2023
(86) PCT No.: PCT/CN2023/084472

§ 371 Date: Apr. 25, 2024

(30) Foreign Application Priority Data
Apr. 29, 2022 (CN) 202210474269.8

(51) Int. Cl. H10K 59/35; H10K 59/88

(52) U.S. Cl. CPC H10K 59/353; H10K 59/351; H10K 59/352; H10K 59/88

(57) ABSTRACT

A display substrate and a display device are provided. The display substrate includes a base substrate and pixels located on the base substrate. Each pixel includes a plurality of sub-pixels; the plurality of sub-pixels includes a first color sub-pixel, a second color sub-pixel, and a third color sub-pixel. A light-emitting region of one pixel is located in one dummy pattern, light-emitting regions of different pixels are located in different dummy patterns; adjacent dummy patterns where light-emitting regions of adjacent pixels are located do not overlap with each other; the dummy pattern includes a circle or an ellipse, a ratio of a major axis to a minor axis of the ellipse ranges from 1.3 to 1.01; and in each pixel among the at least one pixel, a light-emitting region of a second color sub-pixel surrounds at least a portion of a light-emitting region of a first color sub-pixel.

### CROSS-REFERENCE TO RELATED APPLICATION

The present application claims priority of Chinese Patent Application No. 202210474269.8 filed on Apr. 29, 2022, the disclosure of which is incorporated herein by reference in its entirety as part of the present application.

### TECHNICAL FIELD

At least one embodiment of the present disclosure relates to a display substrate and a display device.

### BACKGROUND

An organic light-emitting display (OLED) is a self-luminous device with a series of advantages such as high brightness, full angle of view, fast response speed, and flexible display. In an organic light-emitting diode display device, the conventional arrangement of red sub-pixels, green sub-pixels, and blue sub-pixels may be changed (e.g., by means of dummy pixels, i.e., by sharing some sub-pixels to reduce the count of sub-pixels), which may reduce density of physical sub-pixels while maintaining the same image resolution.

### SUMMARY

Embodiments of the present disclosure provide a display substrate and a display device. The display substrate includes a base substrate and a plurality of pixels located on the base substrate. Each pixel including a plurality of sub-pixels; the plurality of sub-pixels including a first color sub-pixel, a second color sub-pixel, and a third color sub-pixel. A light-emitting region of one pixel is located in one dummy pattern, light-emitting regions of different pixels are located in different dummy patterns, adjacent dummy patterns where light-emitting regions of adjacent pixels are located do not overlap with each other, the dummy pattern includes a circle or an ellipse, a ratio of a major axis to a minor axis of the ellipse ranges from 1.3 to 1.01; and in each pixel among the at least one pixel, a light-emitting region of the second color sub-pixel surrounds at least a portion of a light-emitting region of the first color sub-pixel.

For example, according to an embodiment of the present disclosure, a center of the circle or the ellipse is located between the light-emitting region of the first color sub-pixel and a light-emitting region of the third color sub-pixel; or, a center of the circle or the ellipse is located on an edge of the light-emitting region of the first color sub-pixel, and the edge is an edge close to a light-emitting region of the third color sub-pixel; or, a center of the circle or the ellipse is located on an edge of a light-emitting region of the third color sub-pixel, and the edge is an edge close to the light-emitting region of the first color sub-pixel.

For example, according to an embodiment of the present disclosure, at least one dummy pattern includes a first region and a second region, a light-emitting region of the third color sub-pixel is located in the first region, at least a portion of the light-emitting region of the second color sub-pixel and the light-emitting region of the first color sub-pixel are located in the second region, and the light-emitting region of the second color sub-pixel surrounds an edge of the light-emitting region of the first color sub-pixel away from the light-emitting region of the third color sub-pixel.

For example, according to an embodiment of the present disclosure, in each pixel among the at least one pixel, edges of the light-emitting region of the first color sub-pixel and a light-emitting region of the third color sub-pixel that are close to each other are both straight edges, at least one of edges of the light-emitting region of the first color sub-pixel and the light-emitting region of the third color sub-pixel that are away from each other includes a fold edge or a curved edge, and the fold edge or the curved edge is bent towards the straight edges.

For example, according to an embodiment of the present disclosure, an edge of the light-emitting region of the first color sub-pixel away from the light-emitting region of the third color sub-pixel includes the fold edge or the curve edge, and the second color sub-pixel surrounds the fold edge or the curved edge.

For example, according to an embodiment of the present disclosure, in each pixel among the at least one pixel, the counts of first color sub-pixels and third color sub-pixels are both one, and the count of second color sub-pixels is at least one.

For example, according to an embodiment of the present disclosure, the first color sub-pixel includes a first light-emitting region, the second color sub-pixel includes a second light-emitting region, and the third color sub-pixel includes a third light-emitting region; in each pixel among the at least one pixel, an area of the first light-emitting region and an area of the third light-emitting region are both larger than an area of the second light-emitting region, and a distance between edges of the second light-emitting region and the first light-emitting region that are close to each other is less than a distance between edges of the first light-emitting region and the second light-emitting region that are close to each other.

For example, according to an embodiment of the present disclosure, an area of the first region is equal to an area of the second region.

For example, according to an embodiment of the present disclosure, an area of the light-emitting region of the third color sub-pixel is larger than an area of the light-emitting region of the first color sub-pixel, and an area of the light-emitting region of the first color sub-pixel is larger than an area of the light-emitting region of the second color sub-pixel.

For example, according to an embodiment of the present disclosure, in each pixel among the at least one pixel, edges of the light-emitting region of the first color sub-pixel and a light-emitting region of the third color sub-pixel that are away from each other each includes a fold edge; the fold edge is bent towards a center of the pixel, and an included angle between adjacent line segments in the fold edge in the light-emitting region of at least one of the first color sub-pixel and the third color sub-pixel ranges from 90 degrees to 170 degrees.

For example, according to an embodiment of the present disclosure, in each pixel among the at least one pixel, the count of second color sub-pixels is four, the fold edge of the first color sub-pixel includes four sequentially connected line segments, the four second color sub-pixels are arranged in one-to-one correspondence with the four line segments; a line connecting centers of light-emitting regions of two adjacent second color sub-pixels is a first connection line, a line connecting a center of a light-emitting region of at least one of the two adjacent second color sub-pixels 220 and a center of the dummy pattern is a second connection line, and an included angle between the first connection line and the second connection line ranges from 40 degrees to 80 degrees.

For example, according to an embodiment of the present disclosure, a shape of a light-emitting region of at least one of the four second color sub-pixels is a trapezoid, and an upper bottom of the trapezoid is closer to the light-emitting region of the first color sub-pixel than a lower bottom of the trapezoid.

For example, according to an embodiment of the present disclosure, the second color sub-pixel is a green sub-pixel configured to emit green light, one of the first color sub-pixel and the third color sub-pixel is a red sub-pixel configured to emit red light, and the other of the first color sub-pixel and the third color sub-pixel is a blue sub-pixel configured to emit blue light.

For example, according to an embodiment of the present disclosure, the plurality of dummy patterns corresponding to the plurality of pixels each includes the first region and the second region, and directions pointing from centers of the first regions to centers of the second regions all are the same.

For example, according to an embodiment of the present disclosure, the plurality of dummy patterns corresponding to the plurality of pixels includes at least one first-type dummy pattern and at least one second-type dummy pattern, and each first-type dummy pattern and each second-type dummy pattern each includes the first region and the second region; in the first-type dummy pattern, a direction pointing from a center of the first region to a center of the second region is a first pointing direction; in the second-type dummy pattern, a direction pointing from a center of the first region to a center of the second region is a second pointing direction; and the first pointing direction is opposite to the second pointing direction.

For example, according to an embodiment of the present disclosure, the plurality of dummy patterns further includes at least one third-type dummy pattern and at least one fourth-type dummy pattern, and each third-type dummy pattern and each fourth-type dummy pattern each includes the first region and the second region; in the third-type dummy pattern, a direction pointing from a center of the first region to a center of the second region is a third pointing direction; in the fourth-type dummy pattern, a direction pointing from a center of the first region to a center of the second region is a fourth pointing direction; the third pointing direction is opposite to the fourth pointing direction, and the third pointing direction intersects with the first pointing direction.

For example, according to an embodiment of the present disclosure, the plurality of dummy patterns includes a plurality of dummy pattern rows; the plurality of dummy pattern rows includes a plurality of first dummy pattern rows located in odd-numbered rows and a plurality of second dummy pattern rows located in even-numbered rows; dummy patterns in the plurality of first dummy pattern rows are arranged in an array along a row direction and a column direction, dummy patterns in the plurality of second dummy pattern rows are arranged in an array along the row direction and the column direction; and a first dummy pattern row and a second dummy pattern row adjacent to each other are shifted in the row direction.

For example, according to an embodiment of the present disclosure, the plurality of dummy patterns includes a plurality of first-type dummy patterns and a plurality of second-type dummy patterns; the plurality of first-type dummy patterns is arranged in an array along a first direction and a second direction, the plurality of second-type dummy patterns is arranged in an array along the first direction and the second direction; one kind of rows and columns where the first-type dummy patterns and the second-type dummy patterns are located are arranged alternately along the first direction, and the other kind of rows and columns where the first-type dummy patterns and the second-type dummy patterns are located are arranged alternately along the second direction; one of the first direction and the second direction is a row direction, and the other of the first direction and the second direction is a column direction; a row where first-type dummy patterns are located and a row where adjacent second-type dummy patterns are located are shifted from each other along the row direction; and a column where first-type dummy patterns are located and a column where adjacent second-type dummy patterns are located are shifted from each other along the column direction.

For example, according to an embodiment of the present disclosure, the plurality of dummy patterns includes a plurality of first-type dummy patterns and a plurality of second-type dummy patterns, the plurality of first-type dummy patterns and the plurality of second-type dummy patterns are arranged alternately along at least one of a first direction and a second direction; one of the first direction and the second direction is a row direction, and the other of the first direction and the second direction is a column direction.

For example, according to an embodiment of the present disclosure, at least some pixels each includes a light-emitting element and a driving circuit electrically connected with the light-emitting element; at least one pixel includes one first color sub-pixel, one third color sub-pixel, and an even number of second color sub-pixels; in the at least one pixel, the driving circuit of the one first color sub-pixel and the driving circuit of the one third color sub-pixel are arranged along one of a row direction and a column direction; in the at least one pixel, the driving circuit of the second color sub-pixel and the driving circuit of the one first color sub-pixel are arranged along the other of the row direction and the column direction; and in the at least one pixel, the driving circuit of the second color sub-pixel and the driving circuit of the one third color sub-pixel are arranged along the other of the row direction and the column direction.

For example, according to an embodiment of the present disclosure, the display substrate includes a first display region and a second display region, the first display region surrounds at least a portion of the second display region; the plurality of pixels includes a plurality of first pixels and a plurality of second pixels; at least some of the plurality of first pixels each includes a first light-emitting element and a first driving circuit electrically connected with the first light-emitting element, at least some of the plurality of second pixels each includes a second light-emitting element and a second driving circuit electrically connected with the second light-emitting element; the first light-emitting element, the first driving circuit, and the second driving circuit are all located in the first display region, and the second light-emitting element is located in the second display region; an area of a light-emitting region of the at least one second pixel is smaller than an area of a light-emitting region of the at least one first pixel; or pixels per inch of the plurality of second pixels is lower than pixels per inch of the plurality of first pixels.

Another embodiment of the present disclosure provides a display device, which includes the display substrate according to any one of examples as mentioned above.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic diagram of a partial structure of pixel arrangement of a display substrate provided by an example of an embodiment of the present disclosure.

FIG. 2 is an arrangement diagram of a pixel in a dummy pattern provided by another example according to the embodiment of the present disclosure.

FIG. 3 is a schematic diagram of adjusting the dummy pattern shown in FIG. 2 to an ellipse.

FIG. 4 is an arrangement diagram of a pixel in a dummy pattern provided by another example according to the embodiment of the present disclosure.

FIG. 5 is a schematic diagram of one pixel shown by another example according to the embodiment of the present disclosure.

FIG. 6 is a schematic diagram of one pixel shown by another example according to the embodiment of the present disclosure.

FIG. 7 is a schematic diagram of one pixel shown by another example according to the embodiment of the present disclosure.

FIG. 8 is a schematic diagram of a partial structure of pixel arrangement of the display substrate provided by another example according to the embodiment of the present disclosure.

FIG. 9 is a schematic diagram of a partial structure of pixel arrangement of the display substrate provided by another example according to the embodiment of the present disclosure.

FIG. 10 is a schematic diagram of a partial structure of pixel arrangement of the display substrate provided by another example according to the embodiment of the present disclosure.

FIG. 11 is a schematic diagram of a partial structure of pixel arrangement of the display substrate provided by another example according to the embodiment of the present disclosure.

FIG. 12 is a schematic diagram of a light-emitting element and a driving circuit included in one pixel of the display substrate shown in FIG. 1.

FIG. 13 is a schematic diagram of a planar structure of the display substrate including pixel arrangement shown in FIG. 1.

FIG. 14 and FIG. 15 are pixel arrangements in different examples of the display substrate shown in FIG. 13.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

The feature “parallel” used in the embodiments of the present disclosure include features such as “parallel” in the strict sense, and the cases having certain errors, such as “approximately parallel” or the like, taking into account measurements and errors associated with the measurement of a particular quantity (e.g., limitations of the measurement system), and indicate being within an acceptable range of deviation for a particular value as determined by one of ordinary skill in the art. For example, “approximately” may indicate being within one or more standard deviations, or within 10% or 5% of the stated value. In the case that the quantity of a component is not specifically indicated below in the embodiments of the present disclosure, it means that the component may be one or more, or may be understood as at least one. “At least one” means one or more, and “plurality” means at least two.

The embodiments of the present disclosure provide a display substrate and a display device. The display substrate includes a base substrate and a plurality of pixels located on the base substrate. Each pixel includes a plurality of sub-pixels; the plurality of sub-pixels includes a first color sub-pixel, a second color sub-pixel, and a third color sub-pixel. A light-emitting region of one pixel is located in one dummy pattern, light-emitting regions of different pixels are located in different dummy patterns; adjacent dummy patterns where light-emitting regions of adjacent pixels are located do not overlap with each other; the dummy pattern includes a circle or an ellipse, a ratio of a major axis to a minor axis of the ellipse ranges from 1.3 to 1.01; and in each pixel among the at least one pixel, a light-emitting region of a second color sub-pixel surrounds at least a portion of a light-emitting region of a first color sub-pixel. In the embodiments of the present disclosure, the light-emitting region of each pixel is arranged in the dummy pattern having a shape of circle or ellipse, and the light-emitting region of the second color sub-pixel surrounds at least a portion of the light-emitting region of the first color sub-pixel, which is favorable for weakening graininess and jaggedness of the display substrate when used for display, and alleviating the problem of color cast.

Hereinafter, the display substrate and the display device provided by the embodiments of the present disclosure will be described in conjunction with the accompanying drawings.

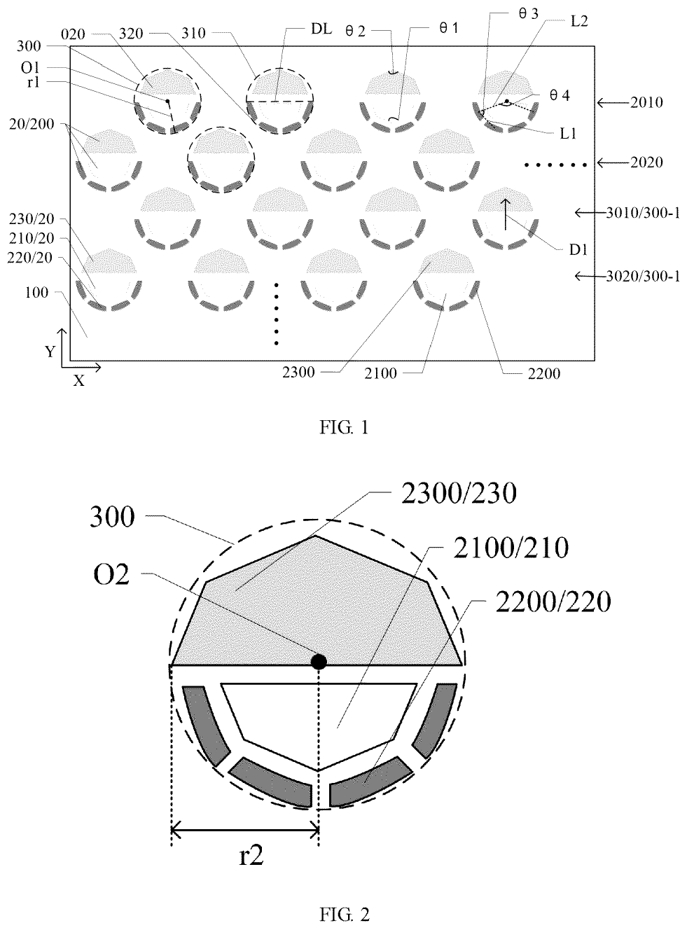

FIG. 1 is a schematic diagram of a partial structure of pixel arrangement of a display substrate provided by an example of an embodiment of the present disclosure. As shown in FIG. 1, the display substrate includes a base substrate 100 and a plurality of pixels 200 located on the base substrate 100. Each pixel 200 includes a plurality of sub-pixels 20; and the plurality of sub-pixels 20 each include a first color sub-pixel 210, a second color sub-pixel 220, and a third color sub-pixel 230.

In some examples, the second color sub-pixel 220 is a green sub-pixel configured to emit green light, one of the first color sub-pixel 210 and the third color sub-pixel 230 is a red sub-pixel configured to emit red light, and the other of the first color sub-pixel 210 and the third color sub-pixel 230 is a blue sub-pixel configured to emit blue light. For example, the first color sub-pixel 210 may be a red sub-pixel, the third color sub-pixel 230 may be a blue sub-pixel, or the first color sub-pixel 210 may be a blue sub-pixel, and the third color sub-pixel 230 may be a red sub-pixel.

Of course, in the embodiment of the present disclosure, the colors of the first color sub-pixel, the second color sub-pixel, and the third color sub-pixel may be interchanged; for example, the first color sub-pixel may be a green sub-pixel, the second color sub-pixel may be a blue sub-pixel, and the third color sub-pixel may be a red sub-pixel, or the first color sub-pixel may be a blue sub-pixel, the second color sub-pixel may be a red sub-pixel, and the third color sub-pixel may be a green sub-pixel.

As shown in FIG. 1, a light-emitting region 020 of one pixel 200 is located in one dummy pattern 300; light-emitting regions 020 of different pixels 200 are located in different dummy patterns 300; adjacent dummy patterns 300 where light-emitting regions 020 of adjacent pixels 200 are located do not overlap with each other. For example, adjacent dummy patterns 300 where light-emitting regions 020 of adjacent pixels 200 are located are spaced apart from each other. For example, edges of adjacent dummy patterns 300 where light-emitting regions 020 of adjacent pixels 200 are located join with each other. For example, edges of adjacent dummy pattern 300 where light-emitting regions 020 of adjacent pixels 200 are arranged along one direction are located are spaced apart from each other, and edges of adjacent dummy patterns 300 where light-emitting regions 020 of adjacent pixels 200 are arranged along the other direction are connected with each other.

For example, the above-described adjacent pixels 200 may refer to two adjacent pixels 200 arranged along an X direction, or may also refer to two adjacent pixels 200 arranged along a Y direction, or may also refer to two adjacent sub-pixels 200 arranged along a tilt direction with a certain included angle to both the X direction and the Y direction. For example, the above-described two adjacent pixels may mean that a central line of the light-emitting regions of two pixels arranged in a certain direction does not pass through the light-emitting regions of other pixels.

As shown in FIG. 1, the dummy pattern 300 includes a circle or an ellipse, and a ratio of a major axis to a minor axis of the ellipse is 1.3 to 1.01. For example, the ratio of the major axis to the minor axis of the ellipse may be 1.25 to 1.05. For example, the ratio of the major axis to the minor axis of the ellipse may be 1.2 to 1.1. For example, the ratio of the major axis to the minor axis of the ellipse may be 1.22 to 1.15.

As shown in FIG. 1, in each pixel 200 among the at least one pixel 200, a light-emitting region of the second color sub-pixel 220 surrounds at least a portion of a light-emitting region of the first color sub-pixel 210. In the embodiment of the present disclosure, the light-emitting region of the second color sub-pixel surrounds at least a portion of the light-emitting region of the first color sub-pixel, so that a straight line extending along at least one of a row direction and a column direction passes through light-emitting regions of sub-pixels with three different colors, which is favorable for alleviating the problem of color cast.

For example, the second color sub-pixel 220 may surround 0.1 to 0.8 of an edge of the light-emitting region of the first color sub-pixel 210. For example, the second color sub-pixel 220 may surround 0.2 to 0.7 of the edge of the light-emitting region of the first color sub-pixel 210. For example, the second color sub-pixel 220 may surround 0.4 to 0.6 of the edge of the light-emitting region of the first color sub-pixel 210. For example, the second color sub-pixel 220 may surround 0.5 to 0.75 of the edge of the light-emitting region of the first color sub-pixel 210.

In the embodiments of the present disclosure, the light-emitting region of each pixel is arranged in the dummy pattern having a shape of circle or ellipse, and the light-emitting region of the second color sub-pixel surrounds at least a portion of the light-emitting region of the first color sub-pixel, so that on the one hand, an edge of a display region has no corners to reduce jaggedness of the edge of the display region; and on the other hand, graininess may be reduced to alleviate the problem of color cast.

For example, the dummy pattern where the pixel is located provided by the present disclosure may be regarded as a “copper coin” biomimetic pattern. As compared with other pattern for arranging a light-emitting region of a pixel, for example, a rectangular region structure for pixel arrangement, a Real structure for pixel arrangement, a triangle structure for pixel arrangement, a mosaic structure for pixel arrangement, or a green green red blue (GGRB) structure for pixel arrangement, the dummy pattern having a shape of circle or ellipse for arranging the light-emitting region of the pixel according to the present disclosure, may have advantages of less jaggedness, less graininess of character, and weaker color cast.

In some examples, as shown in FIG. 1, the first color sub-pixel 210 includes a first light-emitting region 2100, the second color sub-pixel 220 includes a second light-emitting region 2200, and the third color sub-pixel 230 includes a third light-emitting region 2300. Pattern contours of the sub-pixels with three different colors in the dummy pattern 300 shown in FIG. 1 may all be considered as contours of the light-emitting regions. For example, the display substrate further includes a pixel defining pattern, the pixel defining pattern includes a plurality of openings and a defining portion surrounding the plurality of openings, and each opening is configured to limit a light-emitting region of a sub-pixel. Each sub-pixel includes a light-emitting element, the light-emitting element includes a first electrode, a light-emitting layer, and a second electrode sequentially stacked in a direction perpendicular to the base substrate; a portion of the first electrode is exposed by an opening, at least a portion of the light-emitting layer is located within the opening to contact the first electrode exposed by the opening, and the second electrode covers the light-emitting layer; when the light-emitting layer is located in the opening of the pixel defining pattern, the first electrode and the second electrode located on both sides of the light-emitting layer are capable of driving the light-emitting layer in the opening to emit light. For example, the above-described light-emitting region may refer to an effective light-emitting region of the light-emitting element, and a shape of the light-emitting region refers to a two-dimensional shape; for example, the shape of the light-emitting region may be the same as the shape of the opening of the pixel defining pattern. For example, the opening of the pixel defining pattern may be a shape with a smaller size on a side close to the base substrate and a larger size on a side away from the base substrate. For example, a size and a shape of the light-emitting region may be substantially the same as a size and a shape of the opening on the side of the pixel defining pattern that is close to the base substrate.

In some examples, as shown in FIG. 1, at least one dummy pattern 300 includes a first region 310 and a second region 320; the light-emitting region of a third color sub-pixel 230 is located in the first region 310, at least a portion of the light-emitting region of the second color sub-pixel 220 and the light-emitting region of the first color sub-pixel 210 are located in the second region 320; and the light-emitting region of the second color sub-pixel 220 surrounds an edge on a side of the light-emitting region of the first color sub-pixel 210 away from the light-emitting region of the third color sub-pixel 230.

For example, FIG. 1 schematically shows that light-emitting regions of second color sub-pixels 220 are all located in second regions 320, but it is not limited thereto, and the light emitting region of the second color sub-pixel may be partially located in the second region and partially located in the first region.

For example, as shown in FIG. 1, the third color sub-pixel 230, the first color sub-pixel 210, and the second color sub-pixel 220 are arranged sequentially along one direction. For example, the third color sub-pixel 230, the first color sub-pixel 210, and the second color sub-pixel 220 may be arranged sequentially along the row direction, the column direction, or a tilt direction that is parallel neither to the row direction nor to the column direction.

For example, as shown in FIG. 1, both the first region 310 and the second region 320 have a shape of semicircle.

In some examples, as shown in FIG. 1, an area of the first region 310 is equal to an area of the second region 320. For example, the first region 310 and the second region 320 may have shapes of two semicircles with equal areas.

For example, as shown in FIG. 1, a demarcation line DL between the first region 310 and the second region 320 is located between the first light-emitting region 2100 and the third light-emitting region 2300. For example, a circle center of the dummy pattern 300 may be located on the demarcation line DL.

For example, as shown in FIG. 1, a distance between an edge of the light-emitting region of the first color sub-pixel 210 that is close to the demarcation line DL and the demarcation line DL is less than a distance between an edge of the light-emitting region of the third color sub-pixel 230 that is close to the demarcation line DL and the demarcation line DL.

For example, as shown in FIG. 1, the distance between the edge of the light-emitting region of the third color sub-pixel 230 that is close to the demarcation line DL and the demarcation line DL is greater than a distance between an edge of the light-emitting region of the second color sub-pixel 220 that is closest to the demarcation line DL and the demarcation line DL.

In some examples, as shown in FIG. 1, a center of circle or ellipse of the dummy pattern 300 is located between the first light-emitting region 2100 of the first color sub-pixel 210 and the third light-emitting region 2300 of the third color sub-pixel 230.

For example, as shown in FIG. 1, a point located between the first light-emitting region 2100 and the third light-emitting region 2300 is taken as a circle center O1, and a line connecting an edge of the light-emitting region that is farthest away from the circle center O1 and the circle center O1 is taken as a radius r1 of the dummy pattern 300, so, a dummy pattern 300 having a shape of circle may be obtained. For example, if a distance between an edge of a light-emitting region of a sub-pixel with a certain color in the dummy pattern 300 and an edge of the dummy pattern 300 is relatively great, the distance in the position may be adjusted to adjust the shape of the dummy pattern from the above-described circle to an ellipse.

For example, as shown in FIG. 1, the above-described circle center O1 may be located on a line connecting centers of the first light-emitting region 2100 and the third light-emitting region 2300, for example, at any point on the connection line. For example, the above-described edge of the light-emitting region that is farthest away from the circle center O1 may be the edge of the second light-emitting region 2200, or may also be the edge of the third light-emitting region 2300. For example, the edge of the dummy pattern 300 may coincide with at least a portion of the edge of the at least one light-emitting region, or the edge of the dummy pattern 300 may coincide with at least one point of the edge of the at least one light-emitting region, or the edge of the dummy pattern 300 may be located on the outside of the edges of the respective light-emitting regions. In the embodiment of the present disclosure, a direction pointing from the circle center towards the edge of the first light-emitting region or the third light-emitting region is outward, and the above-described “outside” may refer to a side where the edge of the light-emitting region is away from the circle center.

In some examples, as shown in FIG. 1, in each pixel 200 among the at least one pixel 200, edges of the first light-emitting region 2100 of the first color sub-pixel 210 and the third light-emitting region 2300 of the third color sub-pixel 230 that are close to each other are both straight edges; at least one of edges of the first light-emitting region 2100 of the first color sub-pixel 210 and the third light-emitting region 2300 of the third color sub-pixel 230 that are away from each other includes a fold edge or a curved edge; and the fold edge or the curved edge is bent towards the straight edge.

For example, as shown in FIG. 1, straight edges of the first light-emitting region 2100 and the third light-emitting region 2300 that are close to each other are arranged parallel to each other. For example, edges of the first light-emitting region 2100 and the third light-emitting region 2300 that are away from each other may both be fold edges, or both be curved edges, or one of the two is a fold edge, and the other is a curved edge. For example, the edge of the dummy pattern 300 may coincide with at least a portion of the edge of the first light-emitting region 2100 away from the third light-emitting region 2300, or the edge of the dummy pattern 300 may be located on the outside of the edge of the first light-emitting region 2100 away from the third light-emitting region 2300.

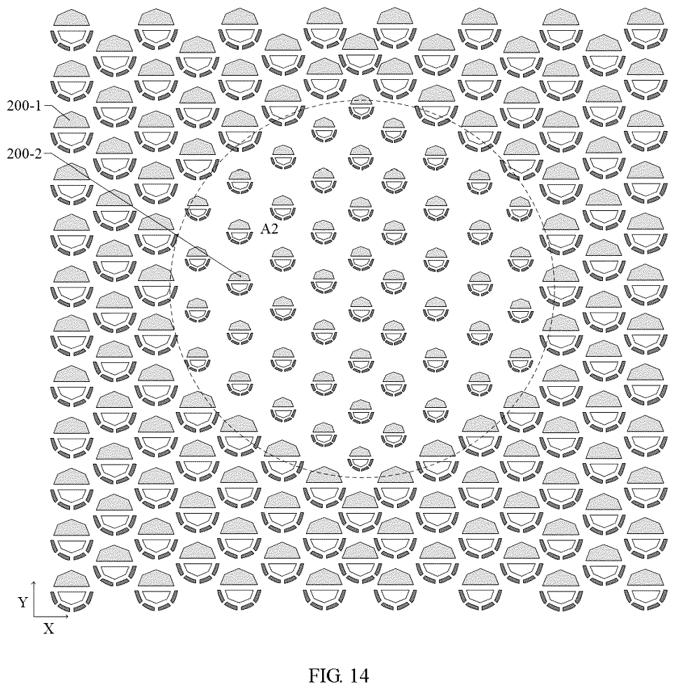

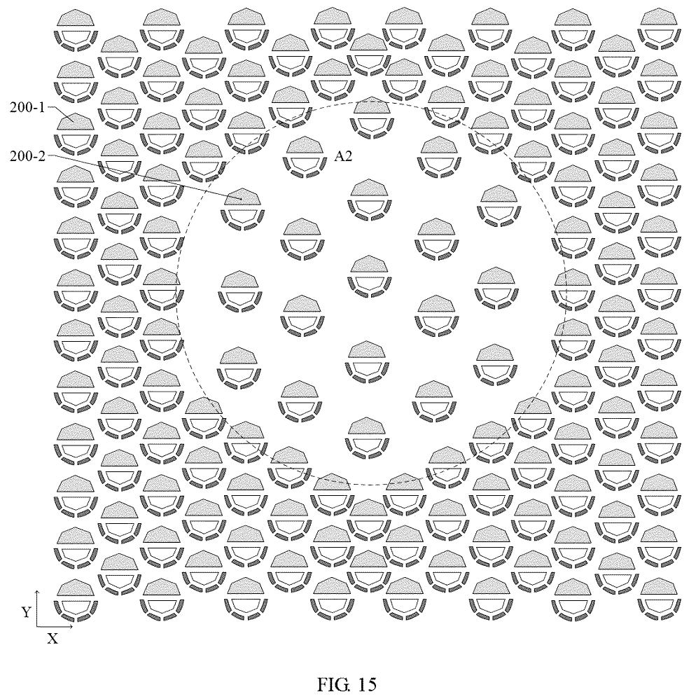

FIG. 1 only schematically shows arrangement of a plurality of pixels, and adjacent pixels may also be arranged more compactly, as shown in FIG. 14 and FIG. 15, so that straight lines extending along the row direction and the column direction may both pass through the light-emitting regions of the sub-pixels with three different colors, so as to further optimize color cast of the display substrate.

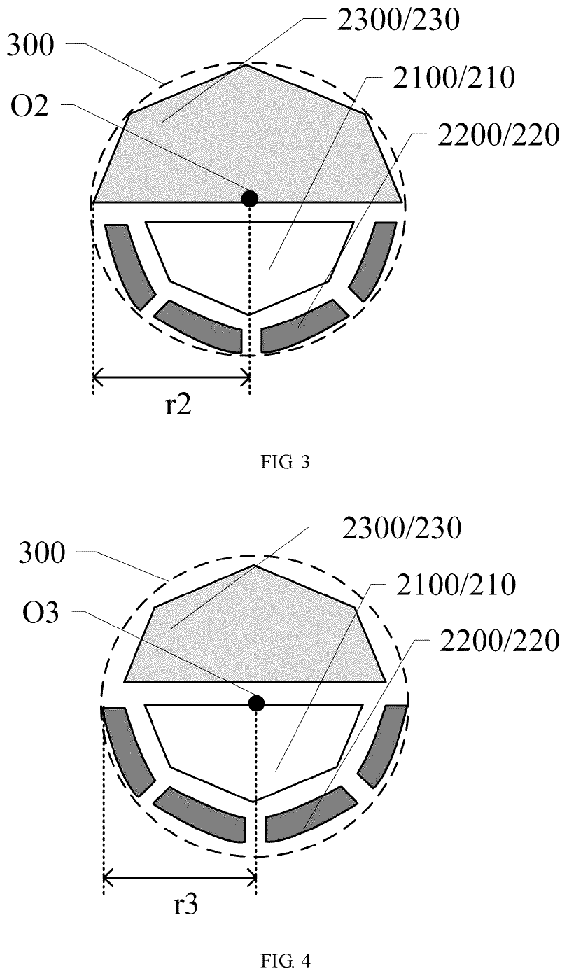

FIG. 2 is an arrangement diagram of a pixel in a dummy pattern provided by another example according to the embodiment of the present disclosure. FIG. 3 is a schematic diagram of adjusting the dummy pattern shown in FIG. 2 to an ellipse.

In some examples, as shown in FIG. 2, a circle center O2 of the dummy pattern 300 is located on an edge of the third light-emitting region 2300 of the third color sub-pixel 230 that is close to the first light-emitting region 2100 of the first color sub-pixel 210; for example, the circle center O2 of the dummy pattern 300 is located on a straight edge of the third light-emitting region 2300.

For example, as shown in FIG. 2, a center located on the straight edge of the third light-emitting region 2300 is taken as the circle center O2, and half of the length of the straight edge of the third light-emitting region 2300 is taken as a radius r2 of the dummy pattern 300, so a dummy pattern 300 having a shape of circle may be obtained.

For example, as shown in FIG. 2, in the dummy pattern 300, a distance between a part of the edge of the third light-emitting region 2300 and the edge of the dummy pattern 300 is greater than a distance between the edge of the second light-emitting region 2200 and the edge of the dummy pattern 300; the distance between the edge of the dummy pattern 300 and the edge of the third light-emitting region 2300 may be adjusted (e.g., the distance may be reduced) to form the dummy pattern 300 having a shape of ellipse shown in FIG. 3.

FIG. 4 is an arrangement diagram of a pixel in a dummy pattern provided by another example according to the embodiment of the present disclosure.

In some examples, as shown in FIG. 4, a circle center O3 of the dummy pattern 300 is located on the edge of the first light-emitting region 2100 of the first color sub-pixel 210 that is close to the third light-emitting region 2300 of the third color sub-pixel 230, for example, the circle center O3 of the dummy pattern 300 is located on the straight edge of the first light-emitting region 2100.

For example, as shown in FIG. 4, a center located on the straight edge of the first light-emitting region 2100 is taken as the circle center O3, and a distance from the center of the first light-emitting region 2100 to the edge of the second light-emitting region 2200 that is farthest from the circle center O3 is taken as a length of a radius r3 of the dummy pattern 300, so a dummy pattern 300 having a shape of circle may be obtained.

Of course, in the embodiment of the present disclosure, the radius r3 of the dummy pattern 300 may be slightly greater than half the length of the straight edge of the third light-emitting region 2300; for example, a ratio of the radius r3 of the dummy pattern 300 to half the length of the straight edge of the third light-emitting region 2300 may be 1.5 to 1.01, or 1.4 to 1.05, or 1.3 to 1.1; the radius r3 of the dummy pattern 300 may be slightly greater than the distance from the center of the straight edge of the first light-emitting region 2100 to the edge of the second light-emitting region 2200 that is farthest from the circle center O3, for example, a ratio of the two may be 1.5 to 1.01, or 1.4 to 1.05, or 1.3 to 1.1.

In some examples, as shown in FIG. 1, the edge of the light-emitting region of the first color sub-pixel 210 away from the light-emitting region of the third color sub-pixel 230 includes a fold edge or a curved edge, and the second color sub-pixel 220 surrounds the fold edge or the curved edge.

In the present disclosure, the edge of the third light-emitting region away from the first light-emitting region is set to a fold edge or a curved edge, and the second color sub-pixel surrounds the fold edge or the curved edge of the first light-emitting region, which can reduce the jagged sense and angular sense of the edge of the display surface.

For example, a ratio of a length of a portion of the fold edge or the curved edge of the light-emitting region of the first color sub-pixel 210 that is surrounded by the second color sub-pixel 220 to a length of the fold edge or the curved edge may be 0.2 to 1. For example, the ratio of the length of the portion of the fold edge or the curved edge of the light-emitting region of the first color sub-pixel 210 that is surrounded by the second color sub-pixel 220 to the length of the fold edge or the curved edge may be 0.3 to 0.95. For example, the ratio of the length of the portion of the fold edge or the curved edge of the light-emitting region of the first color sub-pixel 210 that is surrounded by the second color sub-pixel 220 to the length of the fold edge or the curved edge may be 0.4 to 0.9. For example, the ratio of the length of the portion of the fold edge or the curved edge of the light-emitting region of the first color sub-pixel 210 that is surrounded by the second color sub-pixel 220 to the length of the fold edge or the curved edge may be 0.5 to 0.85. For example, the ratio of the length of the portion of the fold edge or the curved edge of the light-emitting region of the first color sub-pixel 210 that is surrounded by the second color sub-pixel 220 to the length of the fold edge or the curved edge may be 0.6 to 0.8. For example, the ratio of the length of the portion of the fold edge or the curved edge of the light-emitting region of the first color sub-pixel 210 that is surrounded by the second color sub-pixel 220 to the length of the fold edge or the curved edge may be 0.7 to 0.75.

For example, as shown in FIG. 1, in each dummy pattern 300 among at least one dummy pattern 300, an edge of the second light-emitting region 2200 is closer to a straight edge of the third light-emitting region 2300 than the straight edge of the first light-emitting region 2100.

In some examples, as shown in FIG. 1, in each pixel 200 among the at least one pixel 200, an area of the first light-emitting region 2100 and an area of the third light-emitting region 2300 are both larger than an area of the second light-emitting region 2200; and a distance between edges of the second light-emitting region 2200 and the first light-emitting region 2100 that are close to each other is less than a distance between the two straight edges of the first light-emitting region 2100 and the third light-emitting region 2300.

For example, a ratio of the distance between the edges of the second light-emitting region 2200 and the first light-emitting region 2100 that are close to each other to the distance between the two straight edges of the first light-emitting region 2100 and the third light-emitting region 2300 may be 0.5 to 0.95, or 0.6 to 0.9, or 0.7 to 0.85.

In some examples, as shown in FIG. 1, the area of the light-emitting region of the third color sub-pixel 230 is larger than the area of the light-emitting region of the first color sub-pixel 210; and the area of the light-emitting region of the first color sub-pixel 210 is larger than the area of the light-emitting region of the second color sub-pixel 220.

In the embodiment of the present disclosure, the third color sub-pixel whose light-emitting region has the largest area is separately arranged in the first region of the dummy patterns, and the first color sub-pixel and the second color sub-pixel whose light-emitting regions have a smaller area are jointly arranged in the second region of the dummy patterns, which is favorable for improving space utilization in pixel arrangement.

For example, as shown in FIG. 1, in each dummy pattern 300 among the at least one dummy pattern 300, a maximum size of the third light-emitting region 2300 in the X direction is greater than a maximum size of the first light-emitting region 2100 in the X direction; and a length of a line connecting two points on the edge of the second light-emitting region 2200 that are farthest from each other in the X direction is greater than the maximum size of the third light-emitting region 2300 in the X direction.

For example, as shown in FIG. 1, a length of the straight edge of the third light-emitting region 2300 is greater than a length of the straight edge of the first light-emitting region 2100.

For example, as shown in FIG. 1, in each dummy pattern 300 among the at least one dummy pattern 300, a maximum size of the third light-emitting region 2300 in the Y direction is greater than a maximum size of the first light-emitting region 2100 in the Y direction.

For example, as shown in FIG. 1, one portion of an orthogonal projection of the third light-emitting region 2300 on a straight line extending along the X direction only overlaps with an orthogonal projection of the second light-emitting region 2200 on the straight line; and the other portion of the orthogonal projection of the third light-emitting region 2300 on the straight line overlaps with both the orthogonal projection of the second light-emitting region 2200 on the straight line and an orthogonal projection of the first light-emitting region 2100 on the straight line.

For example, as shown in FIG. 1, an orthogonal projection of the first light-emitting region 2100 on a straight line extending along the Y direction completely falls within an orthogonal projection of the second light-emitting region 2200 on the straight line extending along the Y direction. For example, an orthogonal projection of the third light-emitting region 2300 on the straight line extending along the Y direction overlaps with neither the orthogonal projection of the first light-emitting region 2100 on the straight line extending along the Y direction nor the orthogonal projection of the second light-emitting region 2200 on the straight line extending along the Y direction.

For example, as shown in FIG. 1, the shapes of the first light-emitting region 2100 and the third light-emitting region 2300 are approximate shapes. For example, the shapes of the first light-emitting region 2100 and the third light-emitting region 2300 may both be pentagons. The pentagon here includes a standard pentagon and an approximate pentagon; and the approximate pentagon refers to a pentagon in which at least one corner may be rounded. The embodiment of the present disclosure is not limited to that the shapes of the first light-emitting region and the third light-emitting region are pentagons, and at least one of the shapes of the first light-emitting region and the third light-emitting region may be a semicircle.

In some examples, as shown in FIG. 1, in each pixel 200 among the at least one pixel 200, the counts of first color sub-pixels 210 and third color sub-pixels 230 are both one, and the count of second color sub-pixels 220 is at least one.

For example, FIG. 1 schematically shows that each pixel 200 includes four second light-emitting regions 2200, but it is not limited thereto; at least one pixel 200 may include an arc-shaped second light-emitting region 2200, or three second light-emitting regions, or six second light-emitting regions, eight second light-emitting regions, etc. surrounding the first light-emitting region.

In some examples, as shown in FIG. 1, in each pixel 200 among the at least one pixel 200, edges of the light-emitting region of the first color sub-pixel 210 and the light-emitting region of the third color sub-pixel 230 that are away from each other both include a fold edge; and the fold edge is bent towards the center of the pixel 200. An included angle between adjacent line segments in the fold edge in the light-emitting region of at least one of the first color sub-pixel 210 and the third color sub-pixel 230 is 90 degrees to 170 degrees.

For example, as shown in FIG. 1, an included angle θ1 between adjacent line segments in the fold edge of the first light-emitting region 2100 may be 90 degrees to 170 degrees. For example, an included angle θ1 between adjacent line segments in the fold edge of the first light-emitting region 2100 may be 95 degrees to 165 degrees. For example, an included angle θ1 between adjacent line segments in the fold edge of the first light-emitting region 2100 may be 100 degrees to 160 degrees. For example, an included angle θ1 between adjacent line segments in the fold edge of the first light-emitting region 2100 may be 105 degrees to 155 degrees. For example, an included angle θ1 between adjacent line segments in the fold edge of the first light-emitting region 2100 may be 110 degrees to 150 degrees. For example, an included angle θ1 between adjacent line segments in the fold edge of the first light-emitting region 2100 may be 115 degrees to 145 degrees. For example, an included angle θ1 between adjacent line segments in the fold edge of the first light-emitting region 2100 may be 120 degrees to 140 degrees. For example, an included angle θ1 between adjacent line segments in the fold edge of the first light-emitting region 2100 may be 125 degrees to 135 degrees.

For example, the fold edge of the first light-emitting region 2100 may include a plurality of line segments of different lengths, for example, a length of a line segment located in the middle may be greater than a length of a line segment located at the edge, but it is not limited thereto, and lengths of the plurality of line segments included in the first light-emitting region may all be equal.

For example, as shown in FIG. 1, an included angle between the straight edge on the side of the first light-emitting region 2100 that is close to the third light-emitting region 2300 and the fold edge is smaller than the included angle between adjacent line segments in the fold edge.

For example, as shown in FIG. 1, an included angle θ2 between adjacent line segments in the fold edge of the third light-emitting region 2300 may be 90 degrees to 170 degrees. For example, the included angle θ2 between adjacent line segments in the fold edge of the third light-emitting region 2300 may be 95 degrees to 165 degrees. For example, the included angle θ2 between adjacent line segments in the fold edge of the third light-emitting region 2300 may be 100 degrees to 160 degrees. For example, the included angle θ2 between adjacent line segments in the fold edge of the third light-emitting region 2300 may be 105 degrees to 155 degrees. For example, the included angle θ2 between adjacent line segments in the fold edge of the third light-emitting region 2300 may be 110 degrees to 150 degrees. For example, the included angle θ2 between adjacent line segments in the fold edge of the third light-emitting region 2300 may be 115 degrees to 145 degrees. For example, the included angle θ2 between adjacent line segments in the fold edge of the third light-emitting region 2300 may be 120 degrees to 140 degrees. For example, the included angle θ2 between adjacent line segments in the fold edge of the third light-emitting region 2300 may be 125 degrees to 135 degrees.

For example, the fold edge of the third light-emitting region 2300 may include a plurality of line segments of different lengths, for example, a length of a line segment located in the middle may be greater than a length of a line segment located at the edge, but it is not limited thereto, and lengths of the plurality of line segments included in the third light-emitting region may all be equal.

For example, as shown in FIG. 1, an included angle between the straight edge on the side of the third light-emitting region 2300 that is close to the first light-emitting region 2100 and the fold edge is smaller than the included angle between adjacent line segments in the fold edge.

In some examples, as shown in FIG. 1, in each pixel 200 among the at least one pixel 200, the count of second color sub-pixels 220 is four, the fold edge of the first color sub-pixel 210 includes four sequentially connected line segments, the four second color sub-pixels 220 are arranged in one-to-one correspondence with the four line segments; a line connecting centers of light-emitting regions of two adjacent second color sub-pixels 220 is a first connection line L1, a line connecting a center of the light-emitting region of at least one of the two adjacent second color sub-pixels 220 and a center (e.g., the circle center O1) of the dummy pattern 300 is a second connection line L2, and an included angle θ3 between the first connection line L1 and the second connection line L2 is 40 degrees to 80 degrees. The above-described center of a light-emitting region may refer to a geometric center of the light-emitting region, or an intersection point of perpendicular bisectors of respective edges of the light-emitting region, or a point having vertical distances to the respective edges of the light-emitting region that are substantially equal. Of course, there may be a certain margin of error in the above-described center of the light-emitting region. For example, the center of the light-emitting region may be any point within a range with the geometric center of the light-emitting region as a circle center and a radius of 2 μm.

Of course, the embodiment of the present disclosure is not limited that when the edge of the first light-emitting region away from the third light-emitting region is a fold edge, four second light-emitting regions surround the fold edge; and when the edge of the first light-emitting region away from the third light-emitting region is a curved edge, four second light-emitting regions may also surround the curved edge as shown in FIG. 1.

For example, the included angle θ3 between the first connection line L1 and the second connection line L2 is 45 degrees to 75 degrees. For example, the included angle θ3 between the first connection line L1 and the second connection line L2 is 50 degrees to 70 degrees. For example, the included angle θ3 between the first connection line L1 and the second connection line L2 is 55 degrees to 67 degrees. For example, the included angle θ3 between the first connection line L1 and the second connection line L2 is 60 degrees to 65 degrees.

For example, a length ratio of lines connecting the circle center of the dummy pattern 300 and centers of the respective second light-emitting regions 2200 is 0.8 to 1.2. For example, the length ratio of lines connecting the circle center of the dummy pattern 300 and centers of the respective second light-emitting regions 2200 is 0.9 to 1.1. For example, lengths of lines connecting the circle center of the dummy pattern 300 and centers of the respective second light-emitting regions 2200 all are equal.

For example, as shown in FIG. 1, a ratio of an included angle θ4 formed by lines connecting centers of two second light-emitting regions 2200 located at the outermost edge and the circle center of the dummy pattern 300 to an included angle θ2 between two adjacent line segments located in the middle in the fold edge of the third light-emitting region 2300 is 0.8 to 1.2, or 0.9 to 1.1, or 1.

In some examples, as shown in FIG. 1, a shape of the light-emitting region of at least one of four second color sub-pixels 220 located in the same dummy pattern 300 is a trapezoid; and an upper bottom of the trapezoid is closer to the light-emitting region of the first color sub-pixel 210 than a lower bottom of the trapezoid. For example, a length of the upper bottom of the trapezoid in some second light-emitting regions 2200 may be greater than a length of the line segment of the fold edge in the first light-emitting region 2100 opposite to it, while a length of the upper bottom of the trapezoid in other second light-emitting regions 2200 may be less than a length of the line segment of the fold edge in the first light-emitting region 2100 opposite to it.

For example, a shape of the light-emitting region of at least one of four second color sub-pixels 220 located in the same dummy pattern 300 may be an isosceles trapezoid. For example, shapes of four second light-emitting regions 2200 located in the same dummy pattern 300 may all be trapezoids, or may all be isosceles trapezoids.

For example, areas of four second light-emitting regions 2200 located in the same dummy pattern 300 may all be equal; for example, shapes of the four second light-emitting regions 2200 may all be the same.

For example, the four second light-emitting regions 2200 located in the same dummy pattern 300 may be evenly distributed, for example, distributed at equal intervals. For example, a distance between edges of two adjacent second light-emitting regions 2200 that are close to each other may be equal to a distance between edges of the second light-emitting region 2200 and the first light-emitting region 2100 that are close to each other, but it is not limited thereto, for example, the former may be less than the latter.

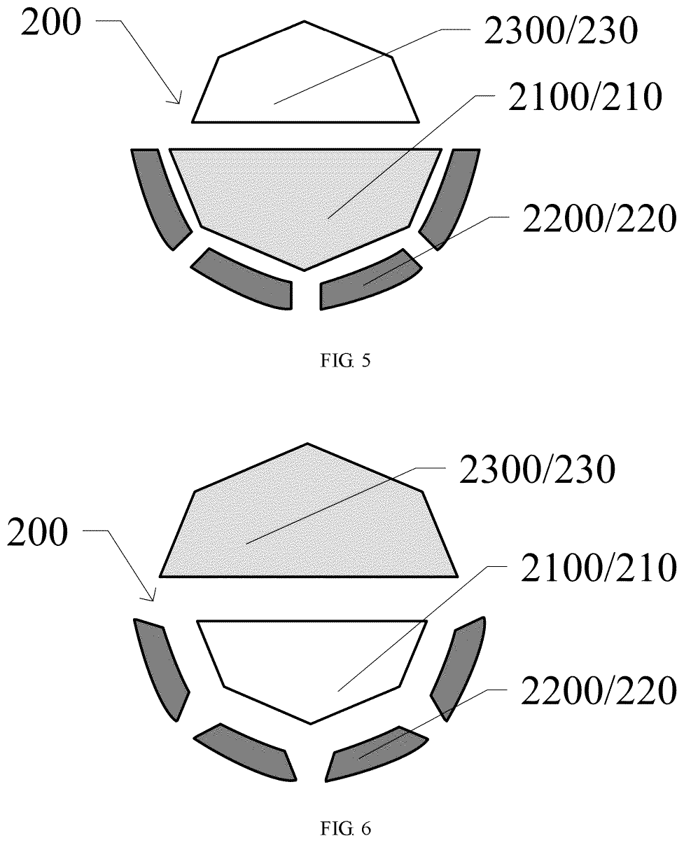

FIG. 5 is a schematic diagram of one pixel shown by another example according to the embodiment of the present disclosure. For example, the pixel shown in FIG. 5 differs from the pixel shown in FIG. 1 in that an area of the first light-emitting region 2100 of the first color sub-pixel 210 is larger than an area of the third light-emitting region 2300 of the third color sub-pixel 230.

For example, in the pixel 200 shown in FIG. 1, the first color sub-pixel 210 is a red sub-pixel, the second color sub-pixel 220 is a green sub-pixel, and the third color sub-pixel 230 is a blue sub-pixel; in the pixel 200 shown in FIG. 5, the first color sub-pixel 210 is a blue sub-pixel, the second color sub-pixel 220 is a green sub-pixel, and the third color sub-pixel 230 is a red sub-pixel.

For example, as shown in FIG. 5, a length of a straight edge on a side of the first light-emitting region 2100 that is close to the third light-emitting region 2300 is greater than a length of a straight edge on a side of the third light-emitting region 2300 that is close to the first light-emitting region 2100.

Except that color and size relationships of the first color sub-pixel and the third color sub-pixel are interchanged, other features in the pixel shown in FIG. 5 may be the same as the corresponding features in the pixel shown in FIG. 1, and no details will be repeated here.

FIG. 6 is a schematic diagram of one pixel shown by another example according to the embodiment of the present disclosure. For example, the pixel shown in FIG. 6 differs from the pixel shown in FIG. 1 in that: an included angle between a waist and a bottom of the trapezoid of the second light-emitting region in the pixel shown in FIG. 6 is different from an included angle between a waist and a bottom of the trapezoid of the second light-emitting region in the pixel shown in FIG. 1. For example, as shown in FIG. 6, the included angle between the waist and the bottom of the trapezoid of the second light-emitting region may be 15 degrees to 60 degrees, 20 degrees to 55 degrees, 25 degrees to 50 degrees, 30 degrees to 45 degrees, or 35 degrees to 40 degrees.

For example, features such as shapes and distribution of the first light-emitting region 2100 and the third light-emitting region 2300 in the pixel shown in FIG. 6 may be the same as the corresponding features in any example shown in FIG. 1 to FIG. 5, and no details will be repeated here.

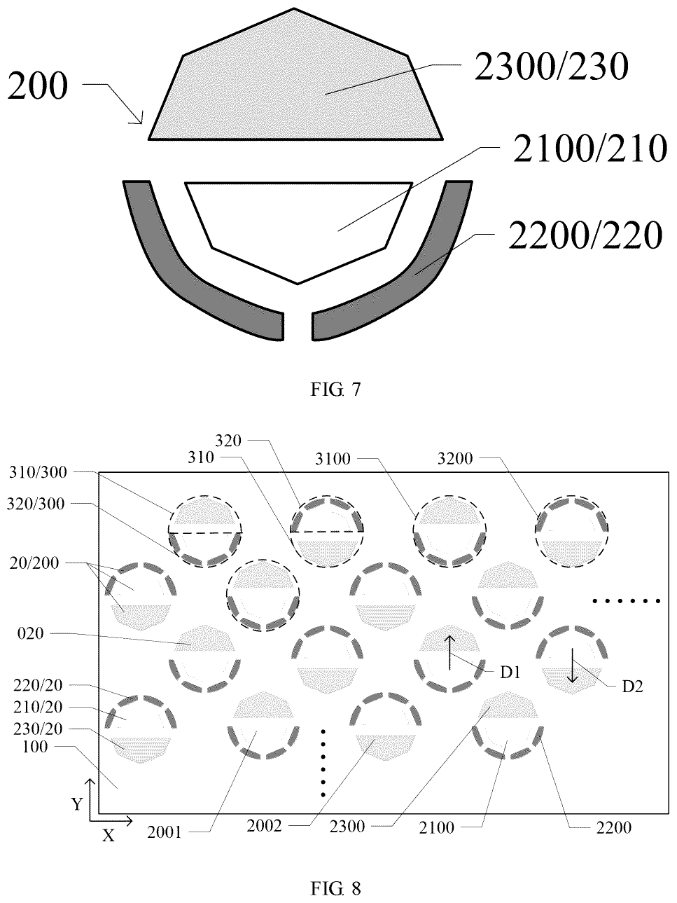

FIG. 7 is a schematic diagram of one pixel shown by another example according to the embodiment of the present disclosure. For example, the pixel shown in FIG. 7 differs from the pixel shown in FIG. 1 in the count of second color sub-pixels 220. For example, as shown in FIG. 7, in at least one pixel 200, the count of second color sub-pixels 220 may be two. For example, in one pixel 200, areas of light-emitting regions of two second color sub-pixels 220 are equal. For example, in one pixel 200, light-emitting regions of the two second color sub-pixels 220 have the same shape and are symmetrically distributed.

For example, features such as shapes and distribution of the first light-emitting region 2100 and the third light-emitting region 2300 in the pixel shown in FIG. 7 may be the same as the corresponding features in any example shown in FIG. 1 to FIG. 5, and no details will be repeated here.

In some examples, as shown in FIG. 1, a plurality of dummy patterns 300 corresponding to the plurality of pixels 200 each include a first region 310 and a second region 320, and directions pointing from centers of the first regions 310 to centers of the second regions 320 all are the same. FIG. 1 schematically shows that a direction D1 pointing from a center of the first region 310 to a center of the second region 320 is the same as a direction indicated by an arrow in the Y direction, but it is not limited thereto, the direction D1 and the Y direction may have a certain included angle, for example, 1 degree to 10 degrees, for example, 2 degrees to 9 degrees, for example, 3 degrees to 8 degrees, for example, 4 degrees to 7 degrees, for example, 5 degrees to 6 degrees. For example, a line connecting centers of the first region 310 and the second region 320 may pass through the circle center O1 of the dummy pattern 300. For example, the direction pointing from the center of the first region 310 to the center of the second region 320 may be the same as the direction pointing from the center of the first light-emitting region 2100 to the center of the third light-emitting region 2300.

For example, as shown in FIG. 1, arrangement directions of the first regions 310 and the second regions 320 in the dummy patterns 300 corresponding to the respective pixels 200 all are the same. FIG. 1 schematically shows that the arrangement direction of the first region 310 and the second region 320 are parallel to the Y direction, for example, the arrangement direction may be a direction opposite to the direction indicated by the arrow in the Y direction, but it is not limited thereto, the arrangement direction may also be a direction the same as the direction indicated by the arrow in the Y direction, or a direction the same as the direction indicated by the arrow in the X direction, or a direction opposite to the direction indicated by the arrow in the X direction, or, the arrangement direction may be parallel to neither the X direction nor the Y direction.

For example, as shown in FIG. 1, among the respective pixels 200, the first color sub-pixel 210, the second color sub-pixel 220, and the third color sub-pixel 230 are arranged along the Y direction. With the X direction as a direction pointing rightwards, and the Y direction as a direction pointing upwards, arrangement directions of first color sub-pixels, second color sub-pixels, and third color sub-pixels in the respective pixels are set to be parallel to an up-down direction, which is favorable for alleviating the problem of color cast in edges on left and right sides when the display substrate is used for display.

For example, one of the X direction and the Y direction shown in FIG. 1 may be a row direction, and the other of the X direction and the Y direction may be a column direction.

In some examples, as shown in FIG. 1, the plurality of dummy patterns 300 includes a plurality of dummy pattern rows 300-1; and the plurality of dummy pattern rows 300-1 includes a plurality of first dummy pattern rows 3010 located in odd-numbered rows and a plurality of second dummy pattern rows 3020 located in even-numbered rows, for example, the first dummy pattern rows 3010 and the second dummy pattern rows 3020 are arranged alternately.

For example, the plurality of pixels 200 includes a plurality of first pixel rows 2010 located in odd-numbered rows and a plurality of second pixel rows 2020 located in even-numbered rows, and the first pixel rows 2010 and the second pixel rows 2020 are arranged alternately.

In some examples, as shown in FIG. 1, dummy patterns 300 in the plurality of first dummy pattern rows 3010 are arranged in an array along the row direction and the column direction, dummy patterns 300 in the plurality of second dummy pattern rows 3020 are arranged in an array along the row direction and the column direction, and a first dummy pattern row 3010 and a second dummy pattern row 3020 adjacent to each other are shifted in the row direction. For example, the first dummy pattern row 3010 and the second dummy pattern row 3020 are shifted by a pitch of one dummy pattern 300 in the row direction.

For example, pixels 200 of the plurality of first pixel rows 2010 are arranged in an array along the row direction and the column directions, pixels 200 of the plurality of second pixel rows 2020 are arranged in an array along the row direction and the column direction, and the first pixel row 2010 and the second pixel row 2020 adjacent to each other are shifted in the row direction. For example, the first pixel row 2010 and the second pixel row 2020 are shifted by a pitch of one pixel 200 in the row direction.

For example, as shown in FIG. 1, a straight line extending along the Y direction may pass through light-emitting regions of pixels 200 in the first pixel row 2010 and the second pixel row 2020. For example, a straight line extending along the Y direction may pass through second light-emitting regions 2200 and third light-emitting regions 2300 of pixels 200 in the first pixel row 2010, as well as second light-emitting regions 2200 and third light-emitting regions 2300 of pixels 200 in the second pixel row 2020.

For example, as shown in FIG. 1, a straight line extending along the X direction may pass through light-emitting regions of pixels 200 in the first pixel row 2010 and the second pixel row 2020. For example, a straight line extending along the X direction may pass through second light-emitting regions 2200 of pixels 200 in the first pixel row 2010 and third light-emitting regions 2300 of pixels 200 in the second pixel row 2020.

In the embodiment of the present disclosure, pixel arrangement is set, which is favorable for improving spatial utilization and color uniformity.

FIG. 8 is a schematic diagram of a partial structure of pixel arrangement provided by another example of the embodiment of the present disclosure. For example, pixel arrangement in the display substrate shown in FIG. 8 differs from pixel arrangement in the display substrate shown in FIG. 1 in that: a plurality of dummy patterns corresponding to a plurality of pixels include at least two different types of dummy patterns; in different types of dummy patterns, directions pointing from centers of first regions to centers of second regions vary, for example, the plurality of pixels include at least two different types of pixels; and in different types of pixels, directions pointing from centers of first light-emitting regions to centers of third light-emitting regions vary.

In some examples, as shown in FIG. 8, the plurality of dummy patterns 300 corresponding to the plurality of pixels 200 includes at least one first-type dummy pattern 3100 and at least one second-type dummy pattern 3200; and each first-type dummy pattern 3100 and each second-type dummy pattern 3200 each include a first region 310 and a second region 320. In the first-type dummy pattern 3100, a direction pointing from a center of the first region 310 to a center of the second region 320 is a first pointing direction D1; in the second-type dummy pattern 3200, a direction pointing from a center of the first region 310 to a center of the second region 320 is a second pointing direction D2, and the first pointing direction D1 is opposite to the second pointing direction D2.

For example, the plurality of pixels 200 includes at least one first-type pixel 2001 and at least one second-type pixel 2002. In the first-type pixel 2001, a direction pointing from a center of a first light-emitting region 2100 to a center of a third light-emitting region 2300 is the first pointing direction D1; in the second-type of pixel 2002, a direction pointing from a center of a first light-emitting region 2100 to a center of a third light-emitting region 2300 is the second pointing direction D2; and the first pointing direction D1 is opposite to the second pointing direction D2.

For example, as shown in FIG. 8, the first pointing direction D1 and the second pointing direction D2 may both be parallel to the Y direction. For example, if a direction pointed by the arrow in the Y direction is upward, the first pointing direction D1 may point upwards, and the second pointing direction D2 may point downwards. For example, the first pointing direction and the second pointing direction may be interchanged.

In some examples, as shown in FIG. 8, the plurality of dummy patterns 300 includes a plurality of first-type dummy patterns 3100 and a plurality of second-type dummy patterns 3200, the plurality of first-type dummy patterns 3100 and the plurality of second-type dummy patterns 3200 is arranged alternately along at least one of the first direction and the second direction; one of the first direction and the second direction is the row direction, and the other of the first direction and the second direction is the column direction.

For example, as shown in FIG. 8, the first-type pixels 2001 and the second-type pixels 2002 are arranged alternately along at least one of the first direction and the second direction.

For example, as shown in FIG. 8, in each pixel row, the first-type pixels 2001 and the second-type pixels 2002 are arranged alternately. For example, pixels in each pixel column are pixels 200 of the same type, for example, pixels 200 in each pixel column all are first-type pixels 2001 or all are second-type pixels 2002. Of course, the embodiment of the present disclosure is not limited to that the first-type pixels and the second-type pixels are arranged alternately only in a pixel row, and the first-type pixels and the second-type pixels may also be arranged alternately both in a pixel row and in a pixel column.

The embodiment of the present disclosure is not limited to that the first-type pixels and the second-type pixels are arranged alternately in the row direction or in the column direction, and may also have two first-type pixels as a first group, two second-type pixels as a second group, and the first groups and the second groups arranged alternately in the row direction or in the column direction, or the count of pixels included in the first group and the second group is not limited to two, or may also be three or more, as long as the same pixel row includes a first-type pixel and a second-type pixel.

For example, as shown in FIG. 8, a straight line extending along the Y direction may pass through light-emitting regions of the first color sub-pixel 210, the second color sub-pixel 220, and the third color sub-pixel 230 in the same pixel 200. For example, a straight line extending along the X direction may pass through a light-emitting region of the third color sub-pixel 230 in one of two adjacent pixels 200, as well as light-emitting regions of the first color sub-pixel 210 and the second color sub-pixel 220 in the other pixel 200.

In the example, the first-type pixels and the second-type pixels in the pixel row are arranged alternately, so that an outermost row of sub-pixels located in a pixel row at an outermost edge of a display surface of the display substrate include sub-pixels with at least two different colors, and an outermost column of sub-pixels located in a pixel column at an outermost edge include sub-pixels with three different colors, which is favorable for reducing probabilities of color cast on upper and lower edges as well as left and right edges of the display surface at the same time.

FIG. 9 is a schematic diagram of a partial structure of pixel arrangement provided by another example of the embodiment of the present disclosure. For example, the pixel arrangement in the display substrate shown in FIG. 9 differs from the pixel arrangement in the display substrate shown in FIG. 8 in arrangement of the first-type pixels 2001 and the second-type pixels 2002, for example, the first-type dummy patterns 3100 and the second-type dummy patterns 3200 in FIG. 8 and FIG. 9 are different in arrangement.

In some examples, as shown in FIG. 9, the plurality of dummy patterns 300 includes a plurality of first-type dummy patterns 3100 and a plurality of second-type dummy patterns 3200; the plurality of first-type dummy patterns 3100 is arranged in an array along the first direction and the second direction; the plurality of second-type dummy patterns 3200 is arranged in an array along the first direction and the second direction; one kind of rows and columns where the first-type dummy patterns 3100 and the second-type dummy patterns 3200 are located are arranged alternately along the first direction, and the other kind of rows and columns where the first-type dummy patterns 3100 and the second-type dummy patterns 3200 are located are arranged alternately along the second direction; one of the first direction and the second direction is a row direction; and the other of the first direction and the second direction is a column direction. A row where the first-type dummy patterns 3100 are located and a row where adjacent second-type dummy patterns 3200 are located are shifted from each other along the row direction; and a column where the first-type dummy patterns 3100 are located and a column where adjacent second-type dummy patterns 3200 are located are shifted from each other along the column direction.

For example, as shown in FIG. 9, the plurality of first-type pixels 2001 is arranged in an array along the first direction and the second direction, the plurality of second-type pixels 2002 is arranged in an array along the first direction and the second direction; one kind of rows and columns where the first-type pixels 2001 and the second-type pixel 2002 are located are arranged alternately along the first direction; and the other kind of rows and columns where the first-type pixels 2001 and the second-type pixels 2002 are located are arranged alternately along the second direction; one of the first direction and the second direction is the row direction, and the other of the first direction and the second direction is the column direction. A row where the first-type pixels 2001 are located and a row where adjacent second-type pixels 2002 are located are shifted from each other along the row direction; and a column where the first-type pixels 2001 are located and a column where adjacent second-type pixels 2002 are located are shifted from each other along the column direction.

For example, as shown in FIG. 9, one of the first pixel row and the second pixel row includes one row of first-type pixels 2001, and the other includes one row of second-type pixels 2002. For example, the plurality of pixels 200 includes a plurality of pixel columns; and each pixel column includes one column of first-type pixels 2001 or one column of second-type pixels 2002.

For example, the first pixel row includes a plurality of first-type pixels 2001 arranged along the row direction, the second pixel row includes a plurality of second-type pixels 2002 arranged along the row direction, and the first pixel row and the second pixel row are arranged alternately in the column direction. Of course, the embodiment of the present disclosure is not limited to that the first pixel row and the second pixel row are arranged alternately in the column direction, and may also have two first pixel rows as a first row group, two second pixel rows as a second row group, the first row groups and the second row groups are arranged alternately in the column direction, or the count of pixel rows included in the first row group and the second row group is not limited to two, or may also be three or more.

The pixel arrangement including first-type pixels and second-type pixels provided by the embodiment of the present disclosure is not limited to the examples shown in FIG. 8 and FIG. 9; for example, only two pixel rows (and/or pixel columns) located at the edge of the display surface include the first-type pixels and the second-type pixels to alleviate color cast of the display surface at upper and lower edges (and/or) left and right edges; or the display surface includes a first display region and a second display region, pixels arranged in the first display region include different types of pixels, and pixels arranged in the second display region only include the same type of pixels, for example, the first display region may be a normal display region, and the second display region may be a region for arranging an under-screen camera; or, the second display region may be a normal display region, and the first display region may be a region for arranging an under-screen camera.

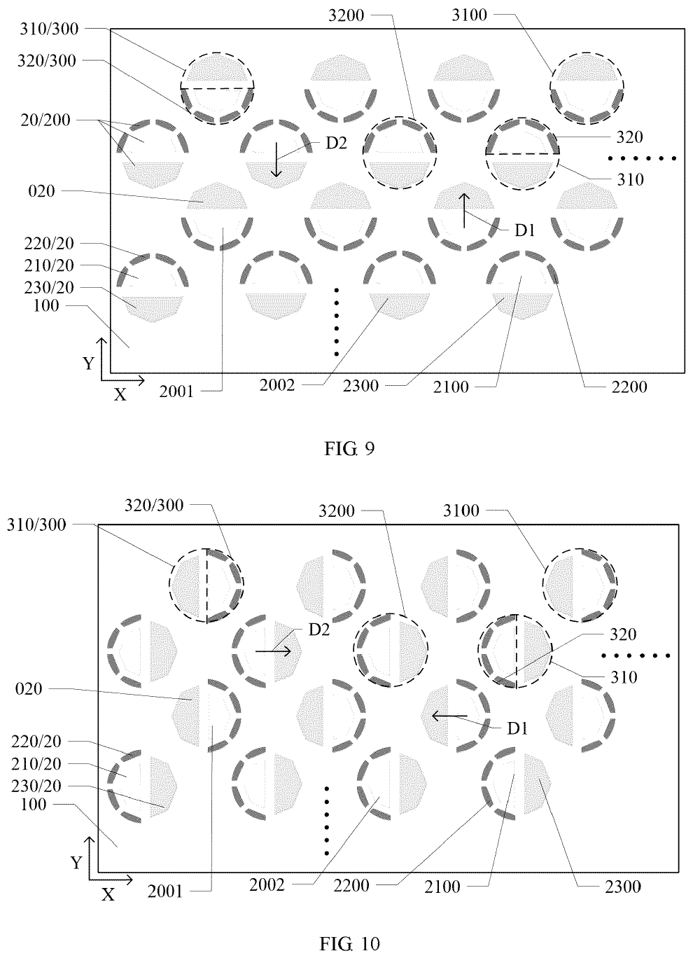

FIG. 10 is a schematic diagram of a partial structure of pixel arrangement provided by another example of the embodiment of the present disclosure. For example, pixel arrangement in the display substrate shown in FIG. 10 differs from pixel arrangement in the display substrate shown in FIG. 9 in that: an orientation of the first pointing direction D1 in the first-type pixel 2001 and an orientation of the second pointing direction D2 in the second-type pixel 2002 are different from the corresponding pointing directions shown in FIG. 9.

For example, the first pointing direction D1 and the second pointing direction D2 shown in FIG. 9 are both parallel to the Y direction; while the first pointing direction D1 and the second pointing direction D2 shown in FIG. 10 are both parallel to the X direction; for example, in one of the two examples shown in FIG. 9 and FIG. 10, the first pointing direction D1 and the second pointing direction D2 are both parallel to the row direction, while in the other example, the first pointing direction D1 and the second pointing direction D2 are both parallel to the column direction.

Except that the first pointing direction and the second pointing direction in the example shown in FIG. 10 are different from the corresponding pointing directions shown in FIG. 9, features such as shapes and arrangement, etc. of the respective pixels in the example shown in FIG. 10 may be the same as the corresponding features shown in FIG. 9, and no details will be repeated here.

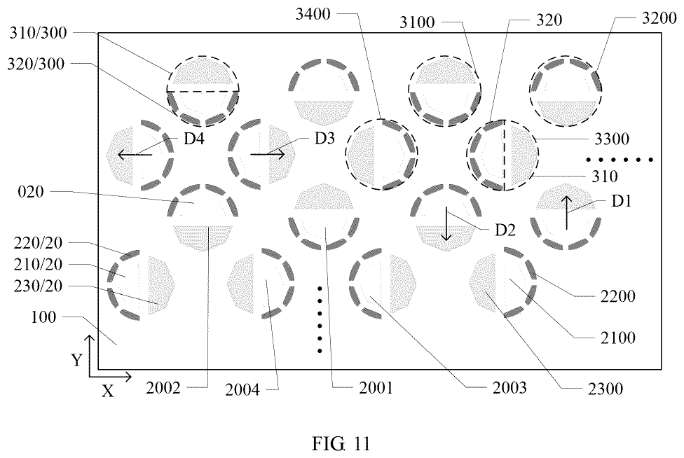

FIG. 11 is a schematic diagram of a partial structure of pixel arrangement provided by another example of the embodiment of the present disclosure. For example, pixel arrangement in the display substrate shown in FIG. 11 differs from pixel arrangement in the display substrate shown in FIG. 9 in that: the plurality of dummy patterns 300 further includes at least one third-type dummy pattern 3300 and at least one fourth-type dummy pattern 3400; each third-type dummy pattern 3300 and each fourth-type dummy pattern 3400 each include a first region 310 and a second region 320; in the third-type dummy pattern 3300, a direction pointing from a center of a first region 310 to a center of a second region 320 is a third pointing direction D3; in the fourth-type dummy pattern 3400, a direction pointing from a center of a first region 310 to a center of a second region 320 is a fourth pointing direction D4; the third pointing direction D3 is opposite to the fourth pointing direction D3, and the third pointing direction D3 intersects with the first pointing direction D1. For example, the third pointing direction D3 is perpendicular to the first pointing direction D1.

For example, as shown in FIG. 11, the plurality of pixels 200 further includes a third-type pixel 2003 and a fourth-type pixel 2004; in the third-type pixel 2003, a direction pointing from a center of a first light-emitting region 2100 to a center of a third light-emitting region 2300 is the third pointing direction D3; and in the fourth-type pixel 2004, a direction pointing from a center of a first light-emitting region 2100 to a center of a third light-emitting region 2300 is the fourth pointing direction D4.

For example, as shown in FIG. 11, one of the first pointing directions D1 and the third pointing direction D3 is parallel to the row direction, and the other of the first pointing direction D1 and the third pointing direction D3 is parallel to the column direction. Of course, the embodiment of the present disclosure is not limited thereto, and the first pointing direction D1 and the third pointing direction D3 may also be parallel to neither the row direction nor the column direction.

For example, as shown in FIG. 11, the plurality of pixels 200 includes a first pixel row and a second pixel row arranged alternately along the column direction; one of the first pixel row and the second pixel row includes the first-type pixel 2001 and the second-type pixel 2002 arranged alternately in the row direction, and the other of the first pixel row and the second pixel row includes the third-type pixel 2003 and the fourth-type pixel 2004 arranged alternately in the row direction.

For example, as shown in FIG. 11, the plurality of pixels 200 includes a first pixel column and a second pixel column arranged alternately along the row direction; one of the first pixel column and the second pixel column includes the first-type pixel 2001 and the second-type pixel 2002 arranged alternately in the column direction, and the other of the first pixel column and the second pixel column includes the third-type pixel 2003 and the fourth-type pixel 2004 arranged alternately in the column direction.

For example, as shown in FIG. 11, a straight line extending along the row direction passes through the third light-emitting region 2300 in one pixel 200 as well as the first light-emitting region 2100 and the second light-emitting region 2200 in the other pixel 200 in a row of pixels 200 located at the outermost edge; and a straight line extending along the column direction passes through the third light-emitting region 2300 in one pixel 200 as well as the first light-emitting region 2100 and the second light-emitting region 2200 in the other pixel 200 in a column of pixels 200 located at the outermost edge, which is favorable for alleviating color cast of the surrounding edges when the display substrate is used for display.

The embodiment of the present disclosure is not limited to arrangement of the first-type pixel, the second-type pixel, the third-type pixel, and the fourth-type pixel as shown in FIG. 11, for example, four different types of pixels repeatedly arranged sequentially along the row direction may also be provided in a same pixel row, and/or four different types of pixels repeatedly arranged sequentially along the column direction may also be provided in a same pixel column; for example, two different types of pixels may also be arranged only in a row of pixels located at the outermost edge, two other different types of pixels are arranged in a column of pixels located at the outermost edge, and a same type of pixels are arranged in other regions, or only two different types of pixels are arranged in other regions; for example, the display region of the display substrate may include a first display region and a second display region, pixels arranged in the first display region include the above-described four different types of pixels, pixels arranged in the second display region may only include a same type of pixels, or include two different types of pixels; for example, the first display region may be a normal display region, and the second display region may be a region for arranging an under-screen camera; or, the second display region may be a normal display region, and the first display region may be a region for arranging an under-screen camera.

Except that the third-type pixel and the fourth-type pixel are provided in the example shown in FIG. 11, features such as shapes and arrangement, etc. of the respective pixels in the example shown in FIG. 11 may be the same as the corresponding features shown in any of the above-described examples, and no details will be repeated here.

The pixels in pixel arrangement shown in FIG. 8 to FIG. 11 may be replaced with the pixels in any example of FIG. 2 to FIG. 7.

As compared with the green green red blue (GGRB) structure for pixel arrangement and the diamond structure for pixel arrangement, the arrangement mode of sub-pixels with different colors in the pixels provided by the embodiment of the present disclosure has less graininess when used for display; and as compared with the green green red blue (GGRB) structure for pixel arrangement, the diamond structure for pixel arrangement, and the real structure for pixel arrangement, the arrangement mode of sub-pixels with different colors in the pixels provided by the embodiment of the present disclosure has alleviated color cast at the edge when used for display.

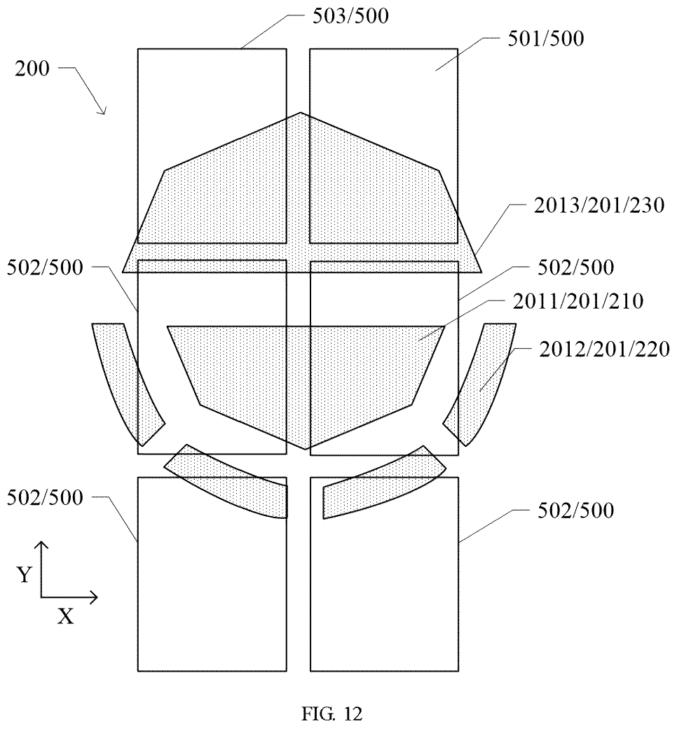

FIG. 12 is a schematic diagram of a light-emitting element and a driving circuit included in one pixel of the display substrate shown in FIG. 1. In some examples, as shown in FIG. 12, at least some pixels 200 each include a light-emitting element 201 and a driving circuit 500 electrically connected with the light-emitting element 201. At least one pixel 200 includes one first color sub-pixel 210, one third color sub-pixel 230, and an even number of second color sub-pixels 220. In the at least one pixel 200, a driving circuit 501 of one first color sub-pixel 210 and a driving circuit 503 of one third color sub-pixel 230 are arranged along one of the row direction and the column direction; in the at least one pixel 200, driving circuits 502 of the second color sub-pixels 220 and the driving circuit 501 of one first color sub-pixel 210 are arranged along the other of the row direction and the column direction; and in the at least one pixel 200, the driving circuits 502 of the second color sub-pixels 220 and the driving circuit 503 of one third color sub-pixel 230 are arranged along the other of the row direction and the column direction. FIG. 12 schematically shows positional relationships between light-emitting regions of the respective sub-pixels and the corresponding driving circuits, but it is not limited thereto, and the positional relationships between the light-emitting regions of the respective sub-pixels and the driving circuits electrically connected with the light-emitting elements of the sub-pixels may be set according to actual products.

For example, as shown in FIG. 12, a light-emitting element 2011 of the first color sub-pixel 210 is electrically connected with the driving circuit 501, a light-emitting element 2013 of the third color sub-pixel 230 is electrically connected with the driving circuit 503; and a light-emitting element 2012 of each second color sub-pixel 220 is electrically connected with a corresponding driving circuit 502. For example, the pixel 200 may include four second color sub-pixels 220, and the driving circuit 500 of the pixel 200 includes four driving circuits 502 respectively electrically connected with the light-emitting elements 2012 of the four second color sub-pixels 220.

For example, as shown in FIG. 12, the driving circuit 501 electrically connected with the light-emitting element 2011 of the first color sub-pixel 210 and the driving circuit 503 electrically connected with the light-emitting element 2013 of the third color sub-pixel 230 are located in a same row; and the four driving circuits 502 respectively electrically connected with the light-emitting elements 2012 of the four second color sub-pixels 220 are arranged in an array, so the six driving circuits included in one pixel are arranged in three rows and two columns. Of course, the embodiment of the present disclosure is not limited thereto, and the six driving circuits included in one pixel may also be arranged in two rows and three columns. For example, the driving circuit 501 electrically connected with the light-emitting element 2011 of the first color sub-pixel 210 and the driving circuit 503 electrically connected with the light-emitting element 2013 of the third color sub-pixel 230 may also be located in a same column.

The embodiment of the present disclosure is not limited to that one pixel includes six second color sub-pixels; and one pixel may also include two second color sub-pixels, at this time, one pixel includes four driving circuits respectively electrically connected with a light-emitting element of one first color sub-pixel, a light-emitting element of one third color sub-pixel, and two light-emitting elements of two second color sub-pixels, and the four driving circuits may be arranged in two rows and two columns.

For example, the driving circuit may include thin film transistors and a capacitor. For example, the driving circuit may be a 7T1C structure, that is, a structure including 7 transistors and 1 capacitor. But it is not limited thereto, and the driving circuit may also be other structure, for example, a structure including other numbers of transistors, for example, an 8T1C structure, a 7T2C structure, a 6T1C structure, a 6T2C structure, or a 9T2C structure, which will not be limited in the embodiments of the present disclosure.

For example, the light-emitting element includes a first electrode, a light-emitting layer, and a second electrode sequentially stacked in a direction perpendicular to the base substrate; the first electrode is located between the light-emitting layer and the base substrate; the first electrode is electrically connected with a thin film transistor in the driving circuit, and the driving circuit is configured to drive the light-emitting layer in the light-emitting element to emit light.

For example, the display substrate further includes a plurality of signal lines electrically connected with the driving circuit, such as data lines, power signal lines, gate lines, light emission control signal lines, initialization signal lines, etc.

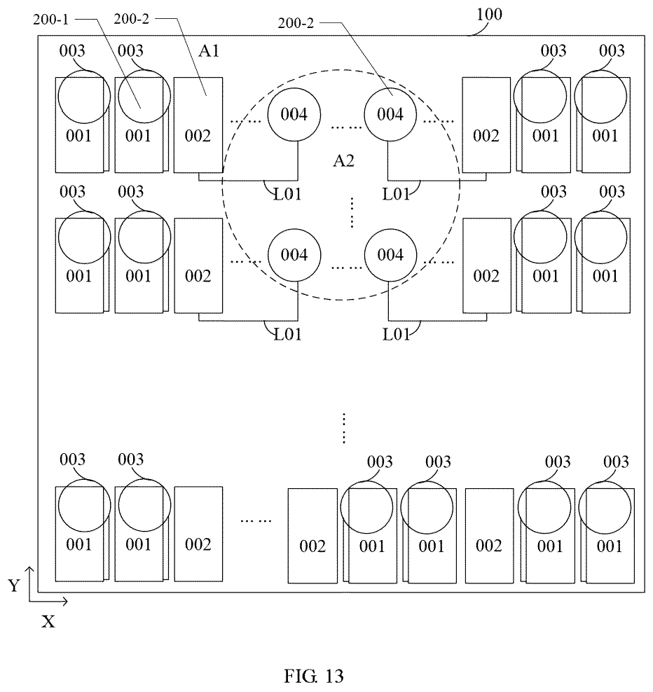

FIG. 13 is a schematic diagram of a planar structure of the display substrate including pixel arrangement shown in FIG. 1; and FIG. 14 and FIG. 15 are pixel arrangement in different examples of the display substrate shown in FIG. 13.

In some examples, as shown in FIG. 13 and FIG. 14, the display substrate includes a first display region A1 and a second display region A2, the first display region A1 surrounds at least a portion of the second display region A2; the plurality of pixels 200 includes a plurality of first pixels 200-1 and a plurality of second pixels 200-2, at least some of the plurality of first pixels 200-1 each include a first light-emitting element 003 and a first driving circuit 001 electrically connected with the first light-emitting element 003, at least some of the plurality of second pixels 200-2 each include a second light-emitting element 004 and a second driving circuit 002 electrically connected with the second light-emitting element 004; the first light-emitting element 003, the first driving circuit 001, and the second driving circuit 002 are all located in the first display region A1, and the second light-emitting element 004 is located in the second display region A2.

For example, the second display region A2 shown in FIG. 13 is located in the top center position of the base substrate 100, for example, four sides of the first display region A1 having a shape of rectangle may all surround the second display region A2 having a shape of circle, that is, the second display region A2 may be surrounded by the first display region A1. The embodiment of the present disclosure is not limited to that the second display region A2 has a shape of circle, but the second display region A2 may also have a shape of rectangle.

For example, the second display region A2 may not be located in the top center position of the base substrate 100 shown in FIG. 13, but may also be located in other position. For example, the second display region A2 may be located at an upper left corner or an upper right corner of the base substrate 100.

For example, as shown in FIG. 13, at least one column of first driving circuits 001 may be provided between two adjacent columns of second driving circuits 002. For example, except second driving circuits 002 located on both sides of the second display region A2 in the X direction, second driving circuits 002 in other position may not be electrically connected with any light-emitting element.

For example, as shown in FIG. 13, at least one first driving circuit 001 may be electrically connected with at least one first light-emitting element 003, and an orthogonal projection of the first driving circuit 001 on the base substrate 100 may overlap at least partially with an orthogonal projection of at least one first light-emitting element 003 on the base substrate 100. The first driving circuit 001 may be configured to supply a driving signal to the first light-emitting element 003 electrically connected therewith, to drive the first light-emitting element 003 to emit light.

For example, as shown in FIG. 13, at least one second driving circuit 002 may be electrically connected with at least one second light-emitting element 004 through a conductor L01 (e.g., a transparent conductor, e.g., ITO), and the second driving circuit 002 may be configured to supply a driving signal to the second light-emitting element 004 electrically connected therewith, to drive the second light-emitting element 004 to emit light. The second light-emitting element 004 and the second driving circuit 002 are located in different regions, there is no overlapping portion between an orthogonal projection of the at least one second driving circuit 002 on the base substrate 100 and an orthogonal projection of the at least one second light-emitting element 004 on the base substrate 100.

For example, the first display region A1 may be a non-transmissive display region, and the second display region A2 may be a transmissive display region, for example, the first display region A1 may be a normal display region, and the second display region A2 may be an under-screen camera region, so, the display panel may directly have required hardware structure such as a photosensitive sensor arranged inside the second display region A2 without drilling a hole, which provides a foundation for implementing a full screen. Because the second display region A2 only includes light-emitting elements and does not include driving circuits, transmittance of the second display region A2 may also be improved.

In some examples, as shown in FIG. 14, an area of a light-emitting region of the at least one second pixel 200-2 is smaller than an area of a light-emitting region of the at least one first pixel 200-1. For example, a ratio of an area of the light-emitting region of one second pixel 200-2 to an area of the light-emitting region of one first pixel 200-1 may be 0.1 to 0.9. For example, the ratio of the area of the light-emitting region of one second pixel 200-2 to the area of the light-emitting region of one first pixel 200-1 may be 0.2 to 0.8. For example, the ratio of the area of the light-emitting region of one second pixel 200-2 to the area of the light-emitting region of one first pixel 200-1 may be 0.3 to 0.7. For example, the ratio of the area of the light-emitting region of one second pixel 200-2 to the area of the light-emitting region of one first pixel 200-1 may be 0.4 to 0.6. For example, the ratio of the area of the light-emitting region of one second pixel 200-2 to the area of the light-emitting region of one first pixel 200-1 may be 0.35 to 0.5.

In the embodiment of the present disclosure, the area of the light-emitting region of the pixel located in the under-screen camera region is set to be smaller than the area of the light-emitting region of the pixel in the normal display region, and the light-emitting region of the second pixel is arranged in the dummy pattern having a shape of circle or ellipse, which improves transmittance of the under-screen camera region; and meanwhile, the light-emitting region is set to have a shape similar to a circular contour, which is favorable for diffraction of light in the under-screen camera region, to improve light-emitting efficiency of light-emitting regions of the respective second pixels.

In some examples, as shown in FIG. 15, pixels per inch (PPI) of the plurality of second pixels 200-2 is lower than PPI of the plurality of first pixels 200-1. For example, a ratio of PPI of the plurality of second pixels 200-2 to PPI of the plurality of first pixels 200-1 may be 0.1 to 0.9. For example, the ratio of PPI of the plurality of second pixels 200-2 to PPI of the plurality of first pixels 200-1 may be 0.2 to 0.8. For example, the ratio of PPI of the plurality of second pixels 200-2 to PPI of the plurality of first pixels 200-1 may be 0.3 to 0.7. For example, the ratio of PPI of the plurality of second pixels 200-2 to PPI of the plurality of first pixels 200-1 may be 0.4 to 0.6. For example, the ratio of PPI of the plurality of second pixels 200-2 to PPI of the plurality of first pixels 200-1 may be 0.35 to 0.5.

For example, within a same area of the first display region A1 and the second display region A2, the count of pixels in the first display region A1 is greater than the count of pixels in the second display region A2. For example, within a region per inch of the first display region A1 and the second display region A2, the count of pixels in the first display region A1 is greater than the count of pixels in the second display region A2.

In the embodiment of the present disclosure, PPI of the under-screen camera region is set to be lower than PPI in the normal display region, and the light-emitting region of the second pixel is arranged in the dummy pattern having a shape of circle or ellipse, which improves transmittance of the under-screen camera region; and meanwhile, the light-emitting region is set to have a shape similar to a circular contour, which is favorable for diffraction of light in the under-screen camera region, to improve light-emitting efficiency of light-emitting regions of the respective second pixels.

For example, in one example of the embodiment of the present disclosure, a pixel whose light-emitting region is located in a dummy pattern having a shape of circle or ellipse may be arranged only in the second display region, and pixel arrangement in the first display region may be different from pixel arrangement in the second display region.

Another embodiment of the present disclosure provides a display device, including the display substrate according to any one of the above-described embodiments.

For example, the display device provided by the embodiment of the present disclosure may be an organic light-emitting diode display device.

For example, the display device may further include a cover plate located on a display side of the display substrate.

For example, the display device may be a mobile phone having an under-screen camera, a tablet personal computer, a laptop, a television, a monitor, a navigator, and any other product or component having a display function; and this embodiment is not limited thereto.

Another embodiment of the present disclosure provides a display substrate; the display substrate is not limited to being used for display, and may also be used in other apparatus such as a camera, a display board, an e-book, an optical device, a rearview mirror, a smart mirror, etc.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A display substrate, comprising:
a base substrate;
a plurality of pixels, located on the base substrate; each pixel comprising a plurality of sub-pixels; the plurality of sub-pixels comprising a first color sub-pixel, a second color sub-pixel, and a third color sub-pixel,
wherein a light-emitting region of one pixel is located in one dummy pattern, light-emitting regions of different pixels are located in different dummy patterns, adjacent dummy patterns where light-emitting regions of adjacent pixels are located do not overlap with each other, the dummy pattern comprises a circle or an ellipse, a ratio of a major axis to a minor axis of the ellipse ranges from 1.3 to 1.01; and
in each pixel among the at least one pixel, a light-emitting region of the second color sub-pixel surrounds at least a portion of a light-emitting region of the first color sub-pixel.

2. The display substrate according to claim 1, wherein a center of the circle or the ellipse is located between the light-emitting region of the first color sub-pixel and a light-emitting region of the third color sub-pixel; or,
a center of the circle or the ellipse is located on an edge of the light-emitting region of the first color sub-pixel, and the edge is an edge close to a light-emitting region of the third color sub-pixel; or,
a center of the circle or the ellipse is located on an edge of a light-emitting region of the third color sub-pixel, and the edge is an edge close to the light-emitting region of the first color sub-pixel.

3. The display substrate according to claim 1, wherein at least one dummy pattern comprises a first region and a second region, a light-emitting region of the third color sub-pixel is located in the first region, at least a portion of the light-emitting region of the second color sub-pixel and the light-emitting region of the first color sub-pixel are located in the second region, and the light-emitting region of the second color sub-pixel surrounds an edge of the light-emitting region of the first color sub-pixel away from the light-emitting region of the third color sub-pixel.

4. The display substrate according to claim 1, wherein, in each pixel among the at least one pixel, edges of the light-emitting region of the first color sub-pixel and a light-emitting region of the third color sub-pixel that are close to each other are both straight edges, at least one of edges of the light-emitting region of the first color sub-pixel and the light-emitting region of the third color sub-pixel that are away from each other comprises a fold edge or a curved edge, and the fold edge or the curved edge is bent towards the straight edges.

5. The display substrate according to claim 4, wherein an edge of the light-emitting region of the first color sub-pixel away from the light-emitting region of the third color sub-pixel comprises the fold edge or the curve edge, and the second color sub-pixel surrounds the fold edge or the curved edge.

6. The display substrate according to claim 1, wherein, in each pixel among the at least one pixel, the counts of first color sub-pixels and third color sub-pixels are both one, and the count of second color sub-pixels is at least one.

7. The display substrate according to claim 1, wherein the first color sub-pixel comprises a first light-emitting region, the second color sub-pixel comprises a second light-emitting region, and the third color sub-pixel comprises a third light-emitting region;
in each pixel among the at least one pixel, an area of the first light-emitting region and an area of the third light-emitting region are both larger than an area of the second light-emitting region, and a distance between edges of the second light-emitting region and the first light-emitting region that are close to each other is less than a distance between edges of the first light-emitting region and the third light-emitting region that are close to each other.

8. The display substrate according to claim 3, wherein an area of the first region is equal to an area of the second region.

9. The display substrate according to claim 3, wherein an area of the light-emitting region of the third color sub-pixel is larger than an area of the light-emitting region of the first color sub-pixel, and an area of the light-emitting region of the first color sub-pixel is larger than an area of the light-emitting region of the second color sub-pixel.

10. The display substrate according to claim 1, wherein, in each pixel among the at least one pixel, edges of the light-emitting region of the first color sub-pixel and a light-emitting region of the third color sub-pixel that are away from each other each comprise a fold edge; the fold edge is bent towards a center of the pixel, and an included angle between adjacent line segments in the fold edge in the light-emitting region of at least one of the first color sub-pixel and the third color sub-pixel ranges from 90 degrees to 170 degrees.

11. The display substrate according to claim 10, wherein, in each pixel among the at least one pixel, the count of second color sub-pixels is four, the fold edge of the first color sub-pixel comprises four sequentially connected line segments, the four second color sub-pixels are arranged in one-to-one correspondence with the four line segments; a line connecting centers of light-emitting regions of two adjacent second color sub-pixels is a first connection line, a line connecting a center of a light-emitting region of at least one of the two adjacent second color sub-pixels 220 and a center of the dummy pattern is a second connection line, and an included angle between the first connection line and the second connection line ranges from 40 degrees to 80 degrees.

12. The display substrate according to claim 11, wherein a shape of a light-emitting region of at least one of the four second color sub-pixels is a trapezoid, and an upper bottom of the trapezoid is closer to the light-emitting region of the first color sub-pixel than a lower bottom of the trapezoid.

13. (canceled)

14. The display substrate according to claim 3, wherein the plurality of dummy patterns corresponding to the plurality of pixels each comprise the first region and the second region, and directions pointing from centers of the first regions to centers of the second regions all are the same.

15. The display substrate according to claim 3, wherein the plurality of dummy patterns corresponding to the plurality of pixels comprises at least one first-type dummy pattern and at least one second-type dummy pattern, and each first-type dummy pattern and each second-type dummy pattern each comprise the first region and the second region;
in the first-type dummy pattern, a direction pointing from a center of the first region to a center of the second region is a first pointing direction; in the second-type dummy pattern, a direction pointing from a center of the first region to a center of the second region is a second pointing direction; and the first pointing direction is opposite to the second pointing direction.

16. The display substrate according to claim 15, wherein the plurality of dummy patterns further comprises at least one third-type dummy pattern and at least one fourth-type dummy pattern, and each third-type dummy pattern and each fourth-type dummy pattern each comprise the first region and the second region;
in the third-type dummy pattern, a direction pointing from a center of the first region to a center of the second region is a third pointing direction; in the fourth-type dummy pattern, a direction pointing from a center of the first region to a center of the second region is a fourth pointing direction; the third pointing direction is opposite to the fourth pointing direction, and the third pointing direction intersects with the first pointing direction.

17. The display substrate according to claim 14, wherein the plurality of dummy patterns comprises a plurality of dummy pattern rows; the plurality of dummy pattern rows comprises a plurality of first dummy pattern rows located in odd-numbered rows and a plurality of second dummy pattern rows located in even-numbered rows; dummy patterns in the plurality of first dummy pattern rows are arranged in an array along a row direction and a column direction, dummy patterns in the plurality of second dummy pattern rows are arranged in an array along the row direction and the column direction; and a first dummy pattern row and a second dummy pattern row adjacent to each other are shifted in the row direction.

18. The display substrate according to claim 15, wherein the plurality of dummy patterns comprises a plurality of first-type dummy patterns and a plurality of second-type dummy patterns; the plurality of first-type dummy patterns is arranged in an array along a first direction and a second direction, the plurality of second-type dummy patterns is arranged in an array along the first direction and the second direction; one kind of rows and columns where the first-type dummy patterns and the second-type dummy patterns are located are arranged alternately along the first direction, and the other kind of rows and columns where the first-type dummy patterns and the second-type dummy patterns are located are arranged alternately along the second direction; one of the first direction and the second direction is a row direction, and the other of the first direction and the second direction is a column direction;
a row where first-type dummy patterns are located and a row where adjacent second-type dummy patterns are located are shifted from each other along the row direction; and a column where first-type dummy patterns are located and a column where adjacent second-type dummy patterns are located are shifted from each other along the column direction.

19. The display substrate according to claim 15, wherein the plurality of dummy patterns comprises a plurality of first-type dummy patterns and a plurality of second-type dummy patterns, the plurality of first-type dummy patterns and the plurality of second-type dummy patterns are arranged alternately along at least one of a first direction and a second direction; one of the first direction and the second direction is a row direction, and the other of the first direction and the second direction is a column direction.

20. The display substrate according to claim 1, wherein at least some pixels each comprise a light-emitting element and a driving circuit electrically connected with the light-emitting element;
at least one pixel comprises one first color sub-pixel, one third color sub-pixel, and an even number of second color sub-pixels; in the at least one pixel, the driving circuit of the one first color sub-pixel and the driving circuit of the one third color sub-pixel are arranged along one of a row direction and a column direction; in the at least one pixel, the driving circuit of the second color sub-pixel and the driving circuit of the one first color sub-pixel are arranged along the other of the row direction and the column direction; and in the at least one pixel, the driving circuit of the second color sub-pixel and the driving circuit of the one third color sub-pixel are arranged along the other of the row direction and the column direction.

21. (canceled)

22. A display device, comprising the display substrate according to claim 1.
